(19) United States
(12) Patent Application Publication
(10) Pub. No.: US 2006/0060958 A1
(43) Pub. Date: Mar. 23, 2006

(54) Semiconductor package, and fabrication method and carrier thereof

(75) Inventors: Chien-Te Chen, Taichung Hsien (TW); Wen-Hsin Wang, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/222,386

(22) Filed: Sep. 7, 2005

(30) Foreign Application Priority Data
Sep. 20, 2004 (TW) 093128413

(51) Int. Cl. H01L 23/48

(52) U.S. Cl. 257/690

(57) ABSTRACT

A semiconductor package, and a fabrication method and a carrier thereof are provided. The fabrication method includes: preparing a core layer having a first surface and an opposed second surface, wherein the first and second surfaces are electrically connected to each other by a plurality of conductive vias; forming a plurality of bond pads on the second surface, wherein the bond pads are electrically connected to the conductive vias, and each of the conductive vias is partly located within a boundary of a corresponding one of the bond pads and is partly located out of the boundary of the corresponding bond pad, such that the carrier is fabricated; mounting and electrically connecting a chip to the first surface; forming an encapsulant on the first surface to encapsulate the chip; and forming solder joints on the bond pads of the second surface. By this arrangement, a popcorn effect is avoided.

### FIELD OF THE INVENTION

The present invention relates to semiconductor packages, and fabrication methods and carriers thereof, and more particularly, to a land grid array (LGA) or ball grid array (BGA) semiconductor package for use in a high frequency product, and a fabricating method and a carrier of the semiconductor package.

### BACKGROUND OF THE INVENTION

For a package structure using a substrate as a carrier, signals of a chip are usually transmitted to bond pads on a bottom surface of the substrate via a plurality of conductive vias formed in the substrate, and the signals can further be transmitted out of the package structure by conductive lands or solder balls formed on the bond pads. Such package structure is customarily referred to as Land Grid Array (LGA) semiconductor package or Ball Grid Array (BGA) semiconductor package.

In order to enhance the electrical performance and solve a signaling problem for a high frequency product, generally a distance between the conductive vias and the bond pads is shortened, that is, a length of conductive traces between the conductive vias and the bond pads is reduced, to shorten a signal transmission path and improve the signal transmission quality.

U.S. Pat. No. 5,796,163 proposes a LGA structure with a conductive land being formed directly on a conductive via to minimize a signal transmission path between the conductive via and the conductive land. As shown in FIGS. 1A and 1B, a conductive via 11 is formed in a core layer 10 of the substrate, and a bond pad 12 for mounting a conductive land or solder ball is formed on a bottom surface of the substrate around the conductive via 11. The bond pad 12 is made of a copper layer, and a nickel/gold (Ni/Au) layer is electroplated on a surface of the bond pad 12. A solder mask 13 is applied on the bottom surface of the substrate, and is formed with an opening 14 for exposing the bond pad 12 and the conductive via 11 located in the centre of the bond pad 12.

Although this design can greatly shorten the signal transmission path, it leads to a serious yield problem in a solder-reflowing process. As the solder-wettable Ni/Au layer is electroplated on the surface of the bond pad 12, it makes solder 25 effectively attach to the bond pad 12 to form a desired conductive land or solder ball after a reflow process. However, since the bond pad 12 surrounds the conductive via 11 in which a solder non-wettable resin material is filled, as shown in FIG. 2, when the solder 25 is applied on the bond pad 12, it cannot be completely wetted to the bond pad 12, thereby leaving a void 20 on the conductive via 11 and trapping air in the void 20.

During the reflow process where the temperature is raised, the air trapped in the void 20 is expanded to make the void 20 burst and result in a popcorn effect, thereby damaging the solder 25 and adversely affecting the quality of solder joint formed by the solder 25. Especially for the LGA package, it has a smaller amount of the solder 25 applied on the bond pad 12 than that of the BGA package, and is thus subjected to more damage caused by the popcorn effect.

In order to solve this problem, U.S. Pat. Nos. 6,191,477 and 6,611,055 propose another design of electrical connection, wherein as shown in FIGS. 3A and 3B, a conductive land 12 is located near a conductive via 11 so as to avoid formation of a void during a process of forming the conductive land 12. However, the conductive land is spaced apart from the conductive via by a certain distance in this structure, which leads to an undesirable long signal transmission path for a high frequency package such as an RF product, thereby causing much noise during signal transmission and adversely affecting the quality of signals.

Therefore, the problem to be solved herein is to properly arrange corresponding locations of a bond pad and a conductive via to assure the quality of signal transmission and avoid formation of a void during a solder-reflowing process for a high frequency semiconductor package.

### SUMMARY OF THE INVENTION

In light of the drawbacks of the conventional technology, an objective of the present invention is to provide a semiconductor package, and a fabrication method and a carrier thereof, so as to enhance the quality of electrical connection.

Another objective of the present invention is to provide a semiconductor package, and a fabrication method and a carrier thereof, so as to avoid formation of a void in solder and burst of the solder.

A further objective of the present invention is to provide a semiconductor package, and a fabrication method and a carrier thereof, which can shorten a signal transmission path.

In accordance with the above and other objectives, the present invention proposes a semiconductor package, comprising: a carrier having a first surface and an opposed second surface, the first and second surfaces being electrically connected to each other by a plurality of conductive vias, wherein a plurality of bond pads are formed on the second surface and are electrically connected to the conductive vias, and wherein each of the conductive vias is partly located within a boundary of a corresponding one of the bond pads and is partly located out of the boundary of the corresponding bond pad; a chip mounted and electrically connected to the first surface of the carrier; an encapsulant formed on the first surface of the carrier, for encapsulating the chip; and a plurality of solder joints formed on the bond pads of the second surface of the carrier.

A fabrication method of the foregoing semiconductor package comprises the steps of: preparing a core layer, which has a first surface and an opposed second surface, wherein the first and second surfaces are electrically connected to each other by a plurality of conductive vias; forming a plurality of bond pads on the second surface of the core layer, wherein the bond pads are electrically connected to the conductive vias, and each of the conductive vias is partly located within a boundary of a corresponding one of the bond pads and is partly located out of the boundary of the corresponding bond pad; mounting and electrically connecting a chip to the first surface of the core layer; forming an encapsulant on the first surface of the core layer to encapsulate the chip; and forming solder joints on the bond pads of the second surface of the core layer.

A carrier proposed in the present invention comprises: a core layer having a first surface and an opposed second surface, wherein the first and second surfaces are electrically connected to each other by a plurality of conductive vias; and a plurality of bond pads formed on the second surface of the core layer and electrically connected to the conductive vias, wherein each of the conductive vias is partly located within a boundary of a corresponding one of the bond pads and is partly located out of the boundary of the corresponding bond pad.

Therefore, by the above positional arrangement of the conductive vias and the bond pads in the present invention, solder applied on the bond pads can be wetted and attached completely to surfaces of the bond pads during a solder-reflowing process, thereby allowing air in a void at an edge of the solder to exhaust completely or avoiding formation of voids. This prevents a popcorn effect and also minimizes a distance between fabricated solder joints and the conductive vias, such that the signal quality of high frequency products is assured and problems in the conventional technology are effectively solved.

### BRIEF DESCRIPTION OF THE DRAWINGS

The present invention can be more fully understood by reading the following detailed description of the preferred embodiments with reference made to accompanying drawings, wherein:

FIGS. 1A and 1B (PRIOR ART) are schematic diagrams of a carrier disclosed by U.S. Pat. No. 5,796,163;

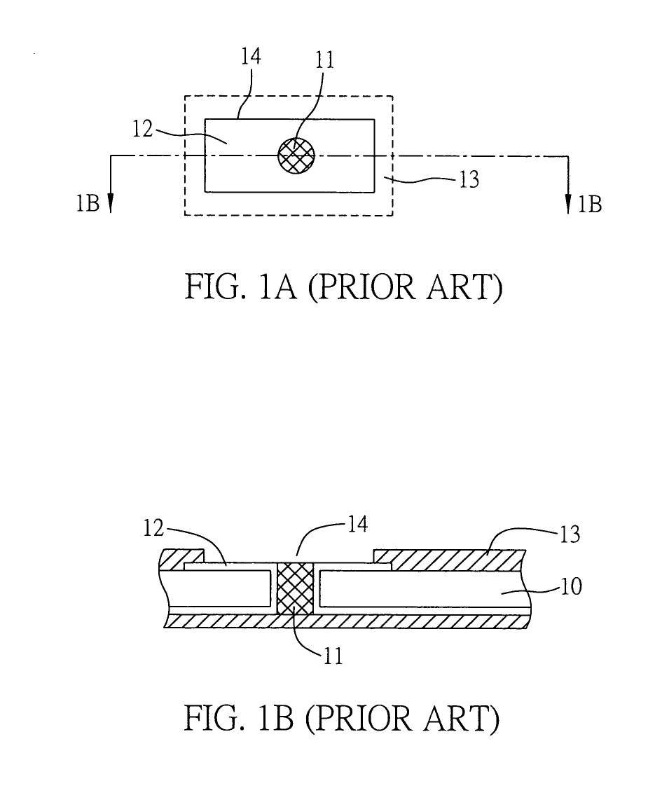

FIG. 2 (PRIOR ART) is a cross-sectional view showing formation of a void during a reflow process for the carrier in FIGS. 1A and 1B;

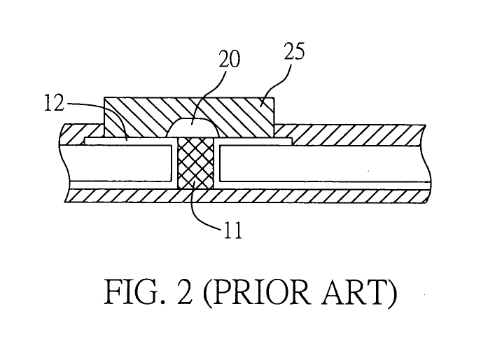

FIGS. 3A and 3B (PRIOR ART) are schematic diagrams of another conventional carrier;

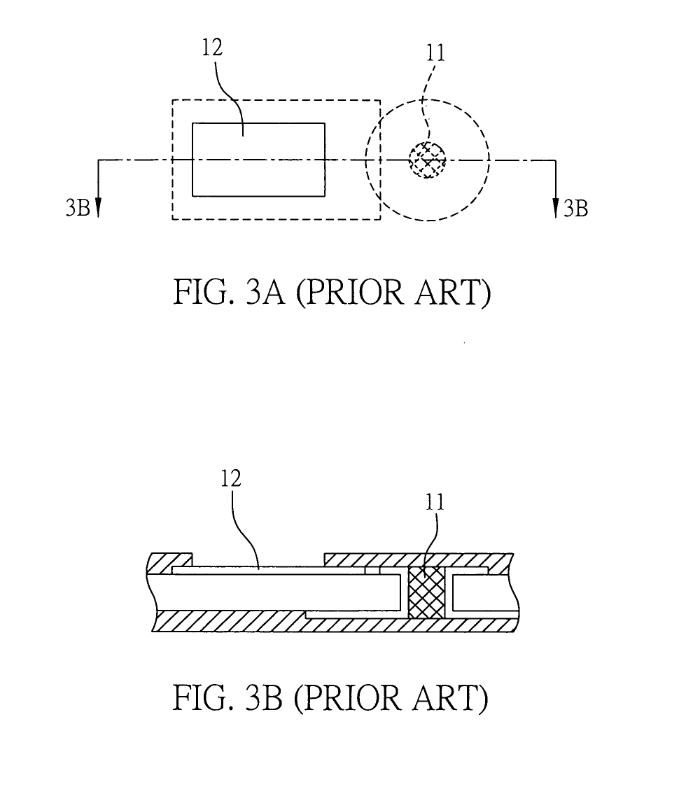

FIGS. 4A and 4B are schematic diagrams of a carrier according to a first preferred embodiment of the present invention;

FIG. 5 is a schematic diagram showing a solder-reflowing process for the carrier according to the first preferred embodiment of the present invention;

FIG. 6 is a cross-sectional view of a semiconductor package fabricated using the carrier according to the first preferred embodiment of the present invention;

FIGS. 7A and 7B are schematic diagrams of a carrier according to a second preferred embodiment of the present invention; and

FIG. 8 is a schematic diagram showing the solder-reflowing process for the carrier according to the second preferred embodiment of the present invention.

### DETAILED DESCRIPTION OF THE PREFERRED EMBODIMENTS

### First Preferred Embodiment

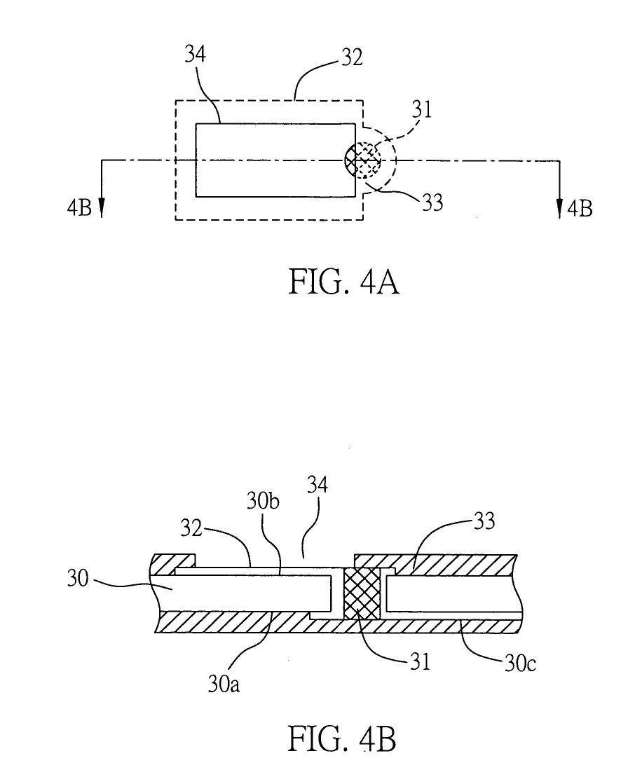

FIGS. 4A and 4B show a carrier according to a first preferred embodiment of the present invention. The carrier is a substrate, and a core layer 30 of the substrate has a first surface 30a and an opposed second surface 30b, wherein the first surface 30a and the second surface 30b are electrically connected to each other by a plurality of conductive vias 31. The first surface 30a is used for carrying a chip, and the second surface 30b is used for external electrical connection.

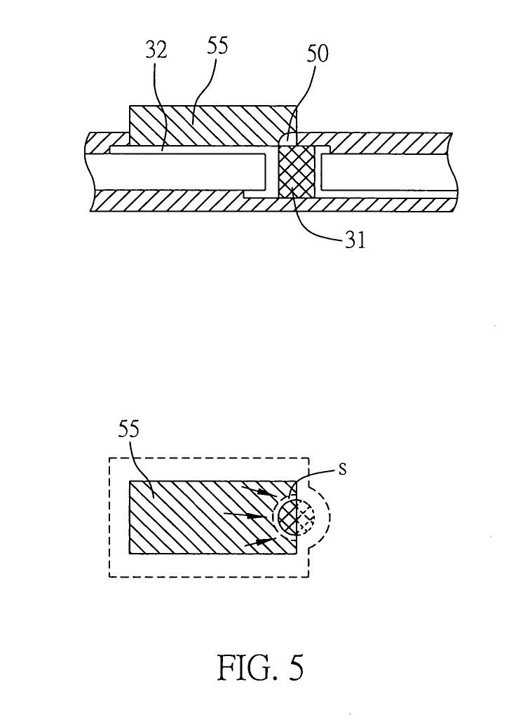

A plurality of conductive traces 30c are disposed on each of the first and second surfaces 30a, 30b, wherein terminals of the conductive traces 30c on the first surface 30a are defined as a plurality of bond fingers and terminals of the conductive traces 30c on the second surface 30b are defined as a plurality of bond pads 32. The bond fingers (not shown) on the first surface 30 are used for electrical connection with the chip, and the bond pads 32 on the second surface 30b are used for applying solder 55 thereon as shown in FIG. 5 in order to fabricate solder joints such as conductive lands or solder balls.

The present invention specifically defines positional arrangement for the bond pads 32 on the second surface 30b and the conductive vias 31. As shown in FIGS. 4A and 4B, the bond pads 32 are electrically connected to the conductive vias 31, and each of the conductive vias 31 is partly located within a boundary of a corresponding one of the bond pads 32 and is partly located out of the boundary of the corresponding bond pad 32. That is, each of the conductive vias 31 is formed on an edge of the corresponding bond pad 32. A solder mask 33 is applied on the carrier and is formed with a plurality of openings 34 for exposing the bond pads 32, such that each of the conductive vias 31 formed on the edge of the corresponding bond pad 32 is partly covered by the solder mask 33 and is partly exposed via a corresponding one of the openings 34 as shown in FIG. 4A.

Referring to FIG. 5, by the above positional arrangement, when the solder 55 is applied on the bond pad 32, with a solder-wettable Ni/Au layer being formed on a surface of the bond pad 32 and a solder non-wettable resin material being filled in the conductive via 31, the solder 55 is wetted and melts to the surface of the bond pad 32 during a reflow process and moves toward the non-wettable conductive via 31 (as indicated by arrows) until the solder 55 melts completely and a void 50 is formed on the conductive via 31. As the conductive via 31 is formed on the edge of the bond pad 32, the void 50 is located at an edge of the solder 55 to allow air in the void 50 to be able to exhaust from the edge of the solder 55 (as indicated by S) during the reflow process, thereby avoiding a popcorn effect and preventing damage to a conductive land or solder ball fabricated from the solder 55. Further as the conductive via 31 is formed on the edge of the bond pad 32, a distance between the conductive via 31 and the fabricated conductive land or solder ball is minimized, such that a signal transmission path is shortened and the signal quality for a high frequency product is assured, thereby effectively solving problems in the conventional technology.

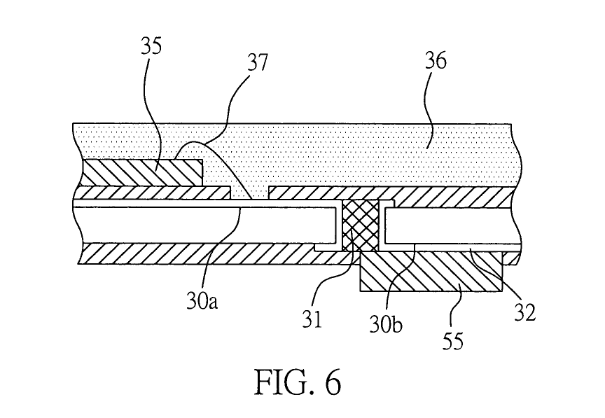

As shown in FIG. 6, a semiconductor package fabricated using the carrier in the present invention further comprises: a chip 35 mounted and electrically connected to the first surface 30a of the carrier, and an encapsulant 36 formed on the first surface 30a to encapsulate the chip 35. Signals of the chip 35 can be transmitted to the first surface 30a of the carrier and then to the bond pads 32 on the second surface 30b of the carrier through the conductive vias 31 that are adjacent to the bond pads 32, such that the signals are further transmitted out of the semiconductor package through the solder joints such as conductive lands or solder balls formed on the bond pads 32 and fabricated from the solder 55.

In this embodiment, the chip 35 can be electrically connected to the first surface 30a of the carrier by bonding wires 37, or the chip can be electrically connected to the first surface of the carrier in a flip-chip manner.

A fabrication method of the above semiconductor package according to the present invention comprises the steps of: preparing a core layer 30 having a first surface 30a and an opposed second surface 30b, wherein the first and second surfaces 30a, 30b are electrically connected to each other by a plurality of conductive vias 31; forming a plurality of bond pads 32 on the second surface 30b of the core layer 30, wherein the bond pads 32 are electrically connected to the conductive vias 31, and each of the conductive vias 31 is partly located within a boundary of a corresponding one of the bond pads 32 and is partly located out of the boundary of the corresponding bond pad 32; applying a solder mask 33 on the first surface 30a and the second surface 30b, and forming a plurality of openings 34 in the solder mask 33 to expose the bond pads 32 and the part of each of the conductive vias 31 located within the boundary of the corresponding bond pad 32; mounting and electrically connecting a chip 35 to the first surface 30a; forming an encapsulant 36 on the first surface 30a to encapsulate the chip 35; and forming a plurality of solder joints such as conductive lands or solder balls from solder 55 on the bond pads 32 of the second surface 30b. This thus completes fabrication of the semiconductor package.

### Second Preferred Embodiment

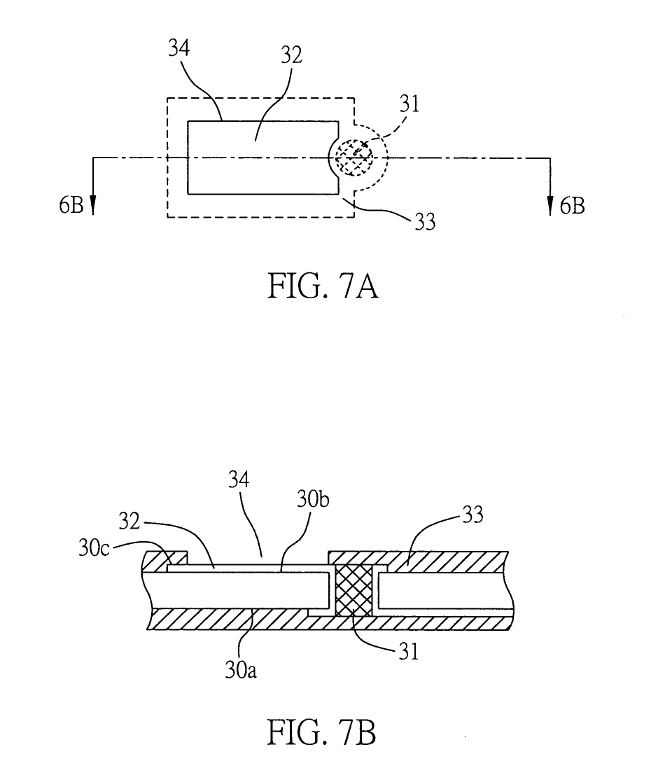

A carrier according to a second preferred embodiment of the present invention is shown in FIGS. 7A and 7B. Similarly to the foregoing first embodiment, the bond pads 32 on the second surface 30b of the carrier in the second embodiment are electrically connected to the conductive vias 31, and each of the conductive vias 31 is partly located within a boundary of a corresponding one of the bond pads 32 and is partly located out of the boundary of the corresponding bond pad 32, that is, the conductive via 31 is formed on an edge of the corresponding bond pad 32. The second embodiment differs from the first embodiment in that, when the solder mask 33 is applied on the carrier, it is formed with openings 34 for exposing the bond pads 32 only but completely covers the conductive vias 31 on the edges of the bond pads 32, such that the conductive vias 31 are not exposed from the solder mask 33.

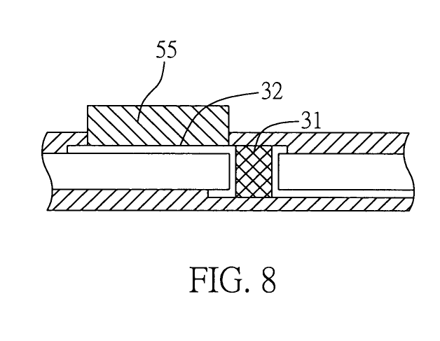

The second embodiment provides the same effects as the first embodiment. When solder 55 is applied on the bond pad 32 during the solder-reflowing process as shown in FIG. 8, as only the bond pad 32 is exposed from the solder mask 33 (the conductive via 31 is not exposed), the solder 55 is wetted and melts completely to be attached to a surface of the bond pad 32 without forming any void on the surface of the bond pad 32, such as no popcorn effect is produced. Further, as the conductive via 31 is formed on the edge of the bond pad 32, a distance between the conductive via 31 and a fabricated conductive land or solder ball is minimized, such that a signal transmission path is shortened and the signal quality for a high frequency product is assured, thereby effectively solving problems in the conventional technology.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package comprising:
a carrier having a first surface and an opposed second surface, the first and second surfaces being electrically connected to each other by a plurality of conductive vias, wherein a plurality of bond pads are formed on the second surface and are electrically connected to the conductive vias, and wherein each of the conductive vias is partly located within a boundary of a corresponding one of the bond pads and is partly located out of the boundary of the corresponding bond pad;
a chip mounted and electrically connected to the first surface of the carrier;
an encapsulant formed on the first surface of the carrier, for encapsulating the chip; and
a plurality of solder joints formed on the bond pads of the second surface of the carrier.

2. The semiconductor package of claim 1, wherein the solder joints are free of physical contact with the conductive vias.

3. The semiconductor package of claim 1, wherein each of the solder joints is partly in physical contact with a corresponding one of the conductive vias.

4. The semiconductor package of claim 1, wherein the carrier further comprises a solder mask having a plurality of openings for exposing the plurality of bond pads.

5. The semiconductor package of claim 4, wherein the conductive vias are completely covered by the solder mask.

6. The semiconductor package of claim 4, wherein each of the conductive vias is partly covered by the solder mask, and the part of each of the conductive vias located within the boundary of the corresponding bond pad is exposed by a corresponding one of the openings of the solder mask.

7. The semiconductor package of claim 1, wherein the chip is electrically connected to the first surface of the carrier by bonding wires.

8. The semiconductor package of claim 1, wherein the chip is electrically connected to the first surface of the carrier in a flip-chip manner.

9. A fabrication method of a semiconductor package, comprising the steps of:
preparing a core layer having a first surface and an opposed second surface, wherein the first and second surfaces are electrically connected to each other by a plurality of conductive vias;
forming a plurality of bond pads on the second surface of the core layer, wherein the bond pads are electrically connected to the conductive vias, and each of the conductive vias is partly located within a boundary of a corresponding one of the bond pads and is partly located out of the boundary of the corresponding bond pad;
mounting and electrically connecting a chip to the first surface of the core layer;
forming an encapsulant on the first surface of the core layer to encapsulate the chip; and
forming solder joints on the bond pads of the second surface of the core layer.

10. The fabrication method of claim 9, wherein the solder joints are free of physical contact with the conductive vias.

11. The fabrication method of claim 9, wherein each of the solder joints is partly in physical contact with a corresponding one of the conductive vias, and a contact position is located at an edge of each of the solder joints.

12. The fabrication method of claim 9, further comprising a step of applying a solder mask on the core layer after forming the bond pads, wherein the solder mask is formed with a plurality of openings for exposing the plurality of bond pads.

13. The fabrication method of claim 12, wherein the conductive vias are completely covered by the solder mask.

14. The fabrication method of claim 12, wherein each of the conductive vias is partly covered by the solder mask, and the part of each of the conductive vias located within the boundary of the corresponding bond pad is exposed by a corresponding one of the openings of the solder mask.

15. The fabrication method of claim 9, wherein the chip is electrically connected to the first surface of the core layer by bonding wires.

16. The fabrication method of claim 9, wherein the chip is electrically connected to the first surface of the core layer in a flip-clip manner.

17. A carrier comprising:
a core layer having a first surface and an opposed second surface, wherein the first and second surfaces are electrically connected to each other by a plurality of conductive vias; and
a plurality of bond pads formed on the second surface of the core layer and electrically connected to the conductive vias, wherein each of the conductive vias is partly located within a boundary of a corresponding one of the bond pads and is partly located out of the boundary of the corresponding bond pad.

18. The carrier of claim 17, further comprising a solder mask having a plurality of openings for exposing the plurality of bond pads.

19. The carrier of claim 18, wherein the conductive vias are completely covered by the solder mask.

20. The carrier of claim 18, wherein each of the conductive vias is partly covered by the solder mask, and the part of each of the conductive vias located within the boundary of the corresponding bond pad is exposed by a corresponding one of the openings of the solder mask.
